(19) United States
(12) Patent Application Publication
(10) Pub. No.: US 2021/0404060 A1
(43) Pub. Date: Dec. 30, 2021

(54) VAPOR DEPOSITION OF TUNGSTEN FILMS

(71) Applicant: ASM IP HOLDING B.V., Almere (NL)

(72) Inventors: Robert Brennan Milligan, Phoenix, AZ (US); Eric James Shero, Phoenix, AZ (US); Shankar Swaminathan, Phoenix, AZ (US); Bhushan Zope, Phoenix, AZ (US)

(21) Appl. No.: 17/353,356

(22) Filed: Jun. 21, 2021

Related U.S. Application Data
(60) Provisional application No. 63/043,279, filed on Jun. 24, 2020.

(51) Int. Cl. C23C 16/455; C23C 16/06

(52) U.S. Cl. CPC C23C 16/45527; C23C 16/06

(57) ABSTRACT

Vapor deposition methods for depositing tungsten-containing thin films are provided. In some embodiments a substrate is contacted with a vapor phase first reactant comprising a tungsten precursor, such as a tungsten oxyhalide, a second reactant such as CO, and a third reactant such as H₂. In some embodiments a substrate is contacted with a vapor phase first reactant comprising a tungsten precursor, such as a tungsten hexacarbonyl, a second reactant comprising a first oxidant, such as H₂O, and a third reactant comprising a reducing agent, such as CO. In some embodiments the deposition process is an ALD process.

### REFERENCE TO RELATED APPLICATIONS

The present application claims priority to U.S. Application No. 63/043,279, filed Jun. 24, 2020, which is incorporated herein by reference in its entirety.

### BACKGROUND OF THE INVENTION

### Field of the Invention

The application generally relates to deposition processes for forming metallic films comprising tungsten. In particular, metallic films comprising tungsten can be deposited by cyclical vapor deposition processes using CO and H₂ as reducing agents.

### Description of the Related Art

Tungsten films are widely used materials in the CMOS industry and as such are deposited for many purposes, e.g., vias between adjacent metal layers, contacts between a metal layer and a device on a silicon substrate, etc. Generally, tungsten hexafluoride (WF₆), tungsten pentachloride (WCl₅) or tungsten hexachloride (WCl₆) have been used for vapor deposition of tungsten films. However, using such tungsten halides may have the disadvantage of generating byproducts that can etch the substrate or contaminate other materials.

### SUMMARY

In one aspect, methods of depositing thin films comprising tungsten by vapor deposition processes are provided. In some embodiments the deposition process is an atomic layer deposition (ALD) process.

In some embodiments a deposition process comprises a plurality of deposition cycles comprising contacting the substrate with a first tungsten precursor, a second reactant and a third reactant. In some embodiments the tungsten precursor comprises a tungsten halide. In some embodiments the tungsten precursor comprises WO₂Cl₄ and/or WOCl₄. In some embodiments the second reactant comprises carbon. In some embodiments the second reactant is a reducing agent. In some embodiments the second reactant comprises CO. In some embodiments the third reactant comprises a reducing agent. In some embodiments the third reactant comprises hydrogen. In some embodiments the third reactant comprises H₂. Excess vapor phase precursor and/or reaction by-products, if any, can be removed from the reaction space between contacting steps.

In some embodiments the substrate is alternately and sequentially contacted with the first precursor, the second reactant and the third reactant. In some embodiments the substrate is simultaneously contacted with the second and third reactants.

In some embodiments the film is an elemental tungsten film. In some embodiments the film may comprise carbon. In some embodiments the film may comprise nitrogen.

In some embodiments the only reactants to contact the substrate in a deposition cycle are the first tungsten precursor, the second reactant and the third reactant. In some embodiments the only reactants to contact the substrate in the deposition process are the first tungsten precursor, the second reactant and the third reactant. In some embodiments the substrate is additionally contacted with an oxygen reactant, such as H₂O. For example the substrate may be contacted with the oxygen reactant after contacting the substrate with the tungsten precursor and prior to contacting the substrate with the second and/or third reactants. In some embodiments the substrate is contacted with the oxygen reactant after being contacted with the first precursor, the second reactant and/or the third reactant.

In some embodiments one, two or more deposition cycles comprise, in order, contacting the substrate with a vapor phase tungsten precursor, such as a tungsten halide, contacting the substrate with a second reactant comprising CO and contacting the substrate with a third reactant comprising H₂. In some embodiments one, two or more deposition cycles comprise alternately and sequentially contacting the substrate with a tungsten halide, CO and H₂. In some embodiments one, two or more deposition cycles comprise, in order, contacting the substrate with a vapor phase tungsten precursor, such as a tungsten halide, and subsequently contacting the substrate simultaneously with a second reactant and third reactant, for example with CO and H₂.

In some embodiments a process for forming a thin film comprising tungsten, such as an elemental tungsten film, comprises one, two or more deposition cycles comprising contacting a substrate in a reaction space with a first reactant comprising a tungsten precursor such as W(CO)₆, contacting the substrate with a second reactant comprising an oxidant, such as H₂O, and contacting the substrate with a third reactant comprising a reducing agent, such as CO. In some embodiments excess reactant and/or reaction byproducts, if any, are removed between contacting steps. In some embodiments, the only reactants utilized in a deposition cycle are the first tungsten precursor and the second and third reactants. In some embodiments the only reactants utilized in a deposition cycle are W(CO)₆, H₂O and CO.

In some embodiments a deposition cycle comprises, in order, contacting a substrate with a vapor phase tungsten precursor, a second reactant comprising H₂O and a third reactant comprising CO. In some embodiments a deposition cycle comprises alternately and sequentially contacting a substrate in a reaction space with W(CO)₆, H₂O and CO.

In some embodiments the deposition process is an atomic layer deposition process. In some embodiments the deposition temperature is between about 200° C. and about 500° C.

### BRIEF DESCRIPTION OF THE DRAWINGS

Embodiments described herein will be better understood from the Detailed Description and from the appended Drawings, which are meant to illustrate and not to limit the invention, and wherein:

FIG. 1 is a simplified cross section view of a gap-fill structure according to certain embodiments.

FIG. 2 is flow-charts illustrating processes for depositing metallic films comprising tungsten by atomic layer deposition (ALD) deposition according to certain embodiments.

FIG. 3 is flow-charts illustrating processes for depositing metallic films comprising tungsten by atomic layer deposition (ALD) deposition according to certain embodiments.

FIGS. 4A-4F are diagrams illustrating deposition processes for depositing metallic films comprising tungsten by an ALD cycle according to certain embodiments.

### DETAILED DESCRIPTION OF THE PREFERRED EMBODIMENT

Vapor deposition processes can be used to deposit material comprising tungsten, such as tungsten films. In one aspect, methods of depositing a thin film comprising tungsten by vapor deposition processes are provided. In some embodiments the thin films are elemental tungsten thin films. In some embodiments the vapor deposition processes utilize a first vapor-phase reactant comprising a tungsten precursor, such as a tungsten oxyhalide, a second vapor-phase reactant and a third vapor-phase reactant. In some embodiments one or both of the second and third reactants can comprise a reducing agent. In some embodiments the second reactant comprises carbon, such as CO. In some embodiment the third reactant comprises hydrogen, for example H₂. In some embodiments the vapor deposition processes utilize a first reactant comprising a tungsten hexacarbonyl, a second reactant comprising an oxidant, such as H₂O, O₃, H₂O₂, N₂O, NO₂ or NO, and a third vapor phase reactant that serves as a reducing agent, such as CO. In some embodiments the deposition process is an atomic layer deposition (ALD) process.

In some embodiments, thin films comprising tungsten are deposited by the disclosed methods. The thin films can be used in a variety of contexts, for example, in vias between adjacent metal layers, or as contacts between a metal layer and a device on a silicon substrate.

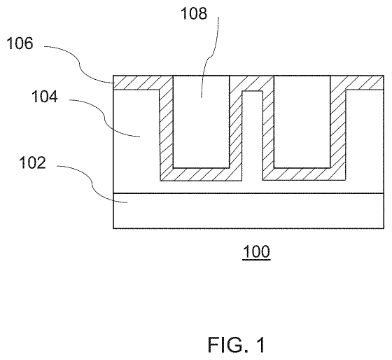

FIG. 1 is a simplified cross-sectional view of a gap-fill structure 100 according to certain embodiments. Referring to FIG. 1, the gap-fill structure 100 comprises a substrate 102, a dielectric layer 104, a barrier/adhesion layer 106 and a gap-fill layer 108 comprising tungsten. The dielectric layer 104 is patterned and the barrier/adhesion layer 126 is formed conformally on the patterned dielectric layer 104, e.g., on the bottom and side of a recess. The gap-fill layer 108 fills the recess. In some embodiments the gap-fill layer 128 comprises tungsten. In some embodiments, the barrier/adhesion layer 106 can comprise titanium and titanium nitride. Other contexts in which the disclosed tungsten-containing thin films may be utilized will be apparent to the skilled artisan.

### Atomic Layer Deposition (ALD)

As noted above, vapor deposition processes are provided for depositing material comprising tungsten. In some embodiments a material comprising tungsten is deposited on a substrate in a reaction space by a deposition cycle comprising contacting the substrate surface with three vapor-phase reactants: a first reactant comprising a tungsten precursor, a second reactant comprising a first reducing agent and a third reactant comprising a second reducing agent. The deposition cycle may be repeated two or more times to deposit a thin film of a desired thickness.

In some embodiments a material comprising tungsten is deposited on a substrate in a reaction space by a deposition process comprising a deposition cycle in which the substrate surface is contacted with a first reactant comprising a tungsten precursor, a second reactant and a third reactant. In some embodiments the second reactant comprises carbon, such as CO. In some embodiments the third reactant comprises H₂ and/or NH₃. In some embodiments the second reactant comprises a first reducing agent and the third reactant comprises a second reducing agent. In some embodiments the first reducing agent is different from the second reducing agent. In some embodiments the first reducing agent and the second reducing agent are the same. In some embodiments the first reducing agent may comprise carbon. In some embodiments the second reducing agent comprises hydrogen. In some embodiments in a deposition cycle the substrate surface is contacted with a first reactant comprising a tungsten precursor, a second reactant comprising CO and a third reactant comprising H₂. In some embodiments the first reactant comprises a vapor phase tungsten precursor, the second reactant is CO and the third reactant is H₂.

In some embodiments in the deposition cycle the substrate is contacted alternately and sequentially with the first reactant comprising the tungsten precursor and then with the second and third reactants. In some embodiments the substrate is contacted first with the first reactant comprising the tungsten precursor and then subsequently contacted simultaneously with the second and third reactants, for example with CO and H₂. In some embodiments the tungsten precursor, the first react and the second reatant are the only reactants utilized in the deposition cycle. For example, in some embodiments the tungsten precursor, CO and H₂ are the only reactants utilized in a deposition cycle.

Although referred to as the first reactant, second reactant and third reactant the three reactants are not necessarily contacted with the substrate in that order in the deposition cycle. In some embodiments the reactants are contacted with the substrate in the order of the first reactant, second reactant and third reactant. In some embodiments the substrate is contacted with one or both of the second or third reactants before the first reactant. In some embodiments the substrate is contacted sequentially with the first reactant comprising the tungsten precursor and then with the second and third reactants.

In some embodiments the substrate is contacted with one or more additional reactants, such as an oxidant. In some embodiments the substrate is contacted with a fourth reactant comprising an oxidant. An oxidant may comprise, for example, at least one of H₂O, O₃, H₂O₂, N₂O, NO₂ or NO. In some embodiments the substrate is contacted with an oxidant after being contacted with a first tungsten precursor and prior to being contacted with a second reactant and/or a third reactant. In some embodiments a substrate is contacted with an oxidant after being contacted with the first tungsten precursor, the second reactant and/or the third reactant.

In some embodiments the first reactant comprising the tungsten precursor can be a tungsten oxyhalide. For example, in some embodiments the tungsten precursor may comprise WOₓCl_{y}, such as WO₂Cl₄, or WOCl₄.

In some embodiments a material comprising tungsten is deposited on a substrate in a reaction space by contacting the substrate surface with a first reactant comprising a tungsten precursor, a second reactant comprising an oxidant, such as H₂O, and a third reactant comprising a reducing agent, such as CO. In some embodiments the second reactant comprises oxygen, such as H₂O, O₃, H₂O₂, N₂O, NO₂ or NO. In some embodiments a deposition process comprises a deposition cycle in which a substrate in a reaction chamber is alternately and sequentially contacted with a first reactant comprising a tungsten precursor, a second reactant comprising H₂O and a third reactant comprising CO. The deposition cycle may be repeated two or more times to deposit a thin film of a desired thickness. In some embodiments the substrate is contacted sequentially with the first reactant comprising the tungsten precursor and then with the second and third reactants. In some embodiments the substrate is contacted first with the first reactant comprising the tungsten precursor and then subsequently contacted simultaneously with the second and third reactants, for example with H₂O and CO. In some embodiments first reactant comprising the tungsten precursor, second reactant comprising an oxidant and third reactant comprising a reducing agent are the only reactants used in the deposition cycle. In some embodiments the tungsten precursor, H₂O and CO are the only reactants utilized in a deposition cycle.

In some embodiments utilizing an oxidant, the tungsten precursor can be a tungsten hexacarbonyl.

In some embodiments CO is not supplied to the reaction space but may be generated from reaction of the tungsten haxacarbonyl and an oxidant, such as H₂O.

In some embodiments conformal thin films comprising tungsten are deposited, for example on a three-dimensional structure on a substrate. Among vapor deposition techniques, ALD has the advantage of typically providing high conformality at relatively low temperatures.

ALD type processes are based on controlled, surface reactions of precursor chemicals. In some embodiments the surface reactions are generally self-limiting. Gas phase reactions are avoided by feeding the precursors alternately and sequentially into the reaction chamber. Vapor phase reactants are separated from each other in the reaction chamber, for example, by removing excess reactants and/or reactant by-products from the reaction chamber between reactant pulses.

Briefly, a substrate is heated to a suitable deposition temperature, generally at lowered pressure. Deposition temperatures are generally maintained below the thermal decomposition temperature of the reactants but at a high enough level to avoid condensation of reactants and to provide the activation energy for the desired surface reactions. Of course, the appropriate temperature window for any given ALD reaction will depend upon the surface termination and reactant species involved. Here, the temperature can be selected in view of the precursors being used and other reaction conditions and is generally at or below about 700° C. and generally at or above about 100° C. In some embodiments the deposition temperature is between about 100° C. and about 250° C., and in some embodiments the deposition temperature is between about 120° C. and about 200° C. In some embodiments, the deposition temperature is below about 500° C., below about 400° C. or below about 300° C. In some instances, the deposition temperature can be below about 200° C., below about 150° C. or below about 100° C. In some embodiments lower deposition temperatures can be achieved, for example, if additional reactants or reducing agents, such as reactants or reducing agents comprising hydrogen, are used in the process.

In a deposition cycle, the surface of the substrate is contacted with a first reactant comprising a vapor phase tungsten precursor. The vapor phase first reactant is also referred to as a tungsten precursor herein. In some embodiments a pulse of vapor phase first tungsten precursor is provided to a reaction space containing the substrate (for example, in time divided ALD). In some embodiments the vapor phase first reactant is provided to the reaction space in a pulse of from about 0.05 to about 10 seconds. In some embodiments the substrate is moved to a reaction space containing vapor phase first tungsten precursor (for example, in space divided ALD, also known as spatial ALD). Conditions can be selected such that no more than about one monolayer of the first tungsten precursor or a species thereof is adsorbed on the first surface of the substrate. Conditions may be selected such that the precursor adsorbs in a self-limiting manner. The appropriate contacting times can be readily determined by the skilled artisan based on the particular circumstances. Excess first reactant and reaction byproducts, if any, are removed from the substrate surface, such as by purging with an inert gas or by removing the substrate from the presence of the first reactant.

The tungsten precursor and additional reactants are typically kept separated and contact the substrate separately. However, in some arrangements, such as hybrid CVD/ALD, or cyclical CVD, processes can allow overlap of the different mutually reactive reactants over the substrate and thus can produce more than a monolayer per cycle.

Vapor phase precursors and/or vapor phase byproducts can be removed from the substrate surface, such as by evacuating a chamber with a vacuum pump and/or by purging (for example, replacing the gas inside a reactor with an inert gas such as argon or nitrogen). Supply of the precursor or reactant to the substrate surface is typically stopped during the removal periods, and may be shunted to a different chamber or to a vacuum pump during the removal periods. Typical removal times are from about 0.05 to 20 seconds, from about 1 to 10 seconds, or from about 1 to 2 seconds. However, other removal times can be utilized if necessary, such as where highly conformal step coverage over extremely high aspect ratio structures or other structures with complex surface morphology is needed.

The surface of the substrate is contacted with a vapor phase second reactant. In some embodiments the second reactant comprises a reducing agent. In some embodiments the second reactant comprises carbon. In some embodiments the second reactant comprises CO. In some embodiments, a pulse of a second reactant is provided to a reaction space containing the substrate. In some embodiments, a pulse of a second reactant is provided to a reaction space containing the substrate for about 0.0.5 to about 60 seconds or more. In some embodiments, the substrate is moved to a reaction space containing the vapor phase second reactant. After sufficient time to react with species of the first reactant on the substrate surface excess second reactant and gaseous byproducts of the surface reaction, if any, are removed from the substrate surface.

Following removal of the second reactant and gaseous byproducts, in some embodiments the surface of the substrate is contacted with a third vapor phase reactant. In some embodiments the third vapor phase reactant comprises a reducing agent. In some embodiments the third vapor phase reactant comprises hydrogen. In some embodiments the third vapor phase reactant comprises H₂. In some embodiments, a pulse of a third reactant is provided to a reaction space containing the substrate. In some embodiments, a pulse of a second reactant is provided to a reaction space containing the substrate for about 0.05 to about 60 seconds or more. In some embodiments, the substrate is moved to a reaction space containing the vapor phase third reactant. After sufficient time to react with species on the substrate surface, excess third reactant and gaseous byproducts of the surface reaction, if any, are removed from the substrate surface.

In some embodiments the second and third reactants may be provided simultaneously or in overlapping pulses. For example, in some embodiments a second reactant comprising CO and a third reactant comprising H₂ are provided simultaneously or in overlapping pulses.

Although referred to as first, second, and third reactants, the reactants may be provided in different orders. In some embodiments the reactants are provided in the same order in each deposition cycle. In some embodiments the reactants are provided in different orders in different deposition cycles.

Contacting and removing are repeated until a thin film of the desired thickness has been formed on the substrate, with each cycle leaving no more than about a molecular monolayer in an ALD or ALD type process, or one or more molecular monolayers in a hybrid CVD/ALD, or cyclical CVD process.

Each reactant is conducted or pulsed into the chamber in the form of vapor phase pulse and contacted with the surface of a substrate. In some embodiments the substrate surface comprises a three-dimensional structure.

As mentioned above, excess precursor or reactant and reaction byproducts, if any, may be removed from the substrate and substrate surface and from proximity to the substrate and substrate surface between pulses of each precursor or reactant. In some embodiments reactant and reaction byproducts, if any, may be removed by purging. Purging may be accomplished for example, with a pulse of inert gas such as nitrogen or argon.

In some embodiments excess precursors (or reactants and/or reaction byproducts, etc.) are removed from the substrate surface or from the area of the substrate by physically moving the substrate from a location containing the precursor, reactant and/or reaction byproducts.

The precursors and reactants employed in the processes may be solid, liquid, or gaseous material under standard conditions (room temperature and atmospheric pressure), provided that they are in vapor phase before they are conducted into the reaction chamber and contacted with the substrate surface.

The steps of contacting the substrate with each precursor and reactant, such as by pulsing, and removing excess precursor or reactant and reaction byproducts are repeated until a thin film of the desired thickness has been formed on the substrate, with each complete cycle typically leaving no more than about a molecular monolayer.

“Pulsing” a vaporized reactant onto the substrate means that the vapor is conducted into the chamber for a limited period of time such that the substrate is exposed to the reactant. Typically, the pulsing time is from about 0.05 seconds to about 60 seconds or longer. However, depending on the substrate type and its surface area, the pulsing time may be even higher than about 60 seconds. Pulsing time can be determined by the skilled artisan based on the particular circumstances.

The mass flow rate of the reactants can be determined by the skilled artisan. In some embodiments, for example for deposition on 300 mm wafers, the flow rate of the reactants is preferably between about 5 sccm and about 1000 sccm, about 10 sccm to about 800 sccm, or about 50 sccm to about 500 sccm.

The pressure in the reaction chamber is typically from about 1 to 70 Torr, or from about 2 to 40 Torr. However, in some cases the pressure will be higher or lower than this range, as can be readily determined by the skilled artisan depending on multiple parameters, such as the particular reactor being used, the process and the precursors.

An excess of reactant is supplied in each phase to saturate the susceptible structure surfaces. Surface saturation ensures reactant occupation of essentially all available reactive sites (subject, for example, to physical size or “steric hindrance” restraints) and thus ensures excellent step coverage. In some arrangements, the degree of self-limiting behavior can be adjusted by, e.g., allowing some overlap of reactant pulses to trade off deposition speed (by allowing some CVD-type reactions) against conformality. Ideal ALD conditions with reactants well separated in time and space provide self-limiting behavior and thus maximum conformality, but steric hindrance results in less than one molecular layer per cycle. Limited CVD reactions mixed with the self-limiting ALD reactions can be used to raise the deposition speed.

In some embodiments, a reaction space can be in a single-wafer ALD reactor or a batch ALD reactor where deposition on multiple substrates takes place at the same time. In some embodiments the substrate on which deposition is desired, such as a semiconductor workpiece, is loaded into a reactor. The reactor may be part of a cluster tool in which a variety of different processes in the formation of an integrated circuit are carried out. In some embodiments a flow-type reactor is utilized. In some embodiments a high-volume manufacturing-capable single wafer ALD reactor is used. In other embodiments a batch reactor comprising multiple substrates is used. For embodiments in which batch ALD reactors are used, the number of substrates can be in the range of 10 to 200, in the range of 50 to 150, or in the range of 100 to 130.

Examples of suitable reactors that may be used include commercially available ALD equipment. In addition to ALD reactors, many other kinds of reactors capable of ALD growth of thin films, including CVD reactors equipped with appropriate equipment and means for pulsing the precursors can be employed. In some embodiments a flow type ALD reactor is used. Reactants are generally kept separate until reaching the reaction chamber, such that shared lines for the precursors are minimized. However, other arrangements are possible.

The deposition processes described herein can optionally be carried out in a reactor or reaction space connected to a cluster tool. In a cluster tool, because each reaction space is dedicated to one type of process, the temperature of the reaction space in each module can be kept constant, which can improve the throughput compared to a reactor in which the substrate is heated up to the process temperature before each run.

In some embodiments, W films are deposited by a deposition cycle comprising alternately and sequentially contacting a substrate with a first reactant comprising a tungsten precursor, a second reactant comprising carbon and oxygen, such as a reactant comprising carbon monoxide (CO), and a third reactant comprising hydrogen, such as H₂. In some embodiments the first reactant comprising the tungsten precursor can be a tungsten oxyhalide. For example, in some embodiments the tungsten precursor may comprise WOₓCl_{y}, such as WO₂Cl₄ or WOCl₄.

In some embodiments where W films being deposited, hydrogen may be used as the reactant comprising hydrogen.

In some embodiments, the reactant comprising carbon and oxide can remove oxygen from the first reactant comprising the tungsten precursor. The hydrogen reactant can remove chloride ligands from the tungsten precursor. The deposition cycle is repeated to deposit a film of the desired thickness.

In some embodiments one or more of the second and third reactants (for example CO and H₂, respectively) may be provided after the first reactant comprising the tungsten precursor. In some embodiments, the tungsten precursor is contacted with the substrate first, followed by the reactant comprising carbon and oxide, and the reactant comprising hydrogen. In some embodiments, the tungsten precursor is contacted with the substrate first, followed by the reactant comprising hydrogen, and the reactant comprising carbon and oxide sequentially.

For example, in some embodiments, a deposition cycle comprises three phases. In a first phase the substrate is contacted with only the first reactant comprising the tungsten precursor. In a second phase the substrate comprising species of the tungsten precursor is contacted with a reactant comprising CO. In a third phase the substrate is contacted with a reactant comprising hydrogen. In some embodiments the second and third phases are combined, such that in a first phase the substrate is only contacted with a tungsten precursor while in a second phase the substrate is contacted with CO and H₂.

In some embodiments the first reactant comprising the tungsten precursor is provided after at least one of the other reactants. In some embodiments, the substrate is contacted with at least one of the carbon monoxide reactant, the hydrogen reactant after the first reactant comprising the tungsten precursor. For example, in some embodiments the carbon monoxide reactant is contacted with the substrate, then the first reactant comprising the tungsten precursor is contacted with the substrate, and the hydrogen reactant can contacted with the substrate. In some embodiments, the hydrogen reactant can contacted with the substrate, then the first reactant comprising the tungsten precursor is contacted with the substrate, and the carbon monoxide reactant is contacted with the substrate.

The deposition cycle is repeated to deposit a thin film comprising tungsten of the desired thickness.

In some embodiments, the thin film comprising tungsten is deposited by a deposition cycle comprising alternately and sequentially contacting a substrate with a first reactant comprising a tungsten precursor, a reactant comprising carbon monoxide, and a reactant comprising H₂. In some embodiments the carbon monoxide reactant and H₂ reactant are provided together. That is, in some embodiments the substrate may be separately contacted with the thin film comprising a tungsten precursor and simultaneously contacted with the reactant comprising carbon monoxide and the reactant comprising H₂.

In some embodiments the order of provision of the reactant may be varied. In some embodiments one or more of the second and third reactants may be provided before the tungsten precursor in the deposition cycle. In that case, the reactant or reactants provided before the first reactant comprising the tungsten precursor will react with adsorbed tungsten species in a subsequent deposition cycle. In some embodiments, the second reactant is provided before the third reactant. For example, the carbon monoxide reactant is provided before an H₂ reactant. In other embodiments the third reactant is provided before the second reactant. For example, an H₂ reactant is provided prior to the carbon monoxide reactant.

In some embodiments, W films are deposited by a deposition cycle comprising alternately and sequentially contacting a substrate with a first reactant comprising a tungsten hexacarbonyl precursor, a second reactant comprising an oxidant, such as H₂O, and a third reactant comprising a reducing agent, such as CO. In some embodiments the first reactant comprising the tungsten precursor can be W(CO)₆.

In some embodiments, the H₂O or other oxidant can react with the tungsten precursor, such as W(CO)₆, to from a monolayer of WOₓ. The reducing agent, such as CO, can then remove oxygen from WOₓ to form a W film. The deposition cycle is repeated to deposit a tungsten film of the desired thickness. In some embodiments the CO is not provided separately to the reaction space but rather can come from reaction of the second reactant with W(CO)₆. In some embodiments CO can be supplied with an additional flow.

In some embodiments one or more of the second and third reactants (for example H₂O and CO, respectively) may be provided after the tungsten precursor, such as W(CO)₆. In some embodiments, W(CO)₆ is contacted with the substrate first, followed by H₂O and CO. In some embodiments, tungsten hexacarbonyl is contacted with the substrate first, followed by H₂O, and CO sequentially.

For example, in some embodiments, the film deposition cycle (comprises three phases. In a first phase the substrate is contacted with only W(CO)₆. In a second phase the substrate comprising species of the tungsten precursor adsorbed on the surface is contacted with H₂O. In a third phase the substrate is contacted with CO. In some embodiments the second and third phases are combined, such that in a first phase the substrate is only contacted with W(CO)₆ while in a second phase the substrate is contacted with H₂O and CO.

In some embodiments W(CO)₆ is provided after at least one of the other reactants. For example, in some embodiments H₂O is contacted with the substrate, then W(CO)₆ is contacted with the substrate, and then CO can be contacted with the substrate. In some embodiments, CO can be contacted with the substrate, then W(CO)₆ is contacted with the substrate, and then H₂O is contacted with the substrate.

The deposition cycle is repeated to deposit a W thin film of the desired thickness.

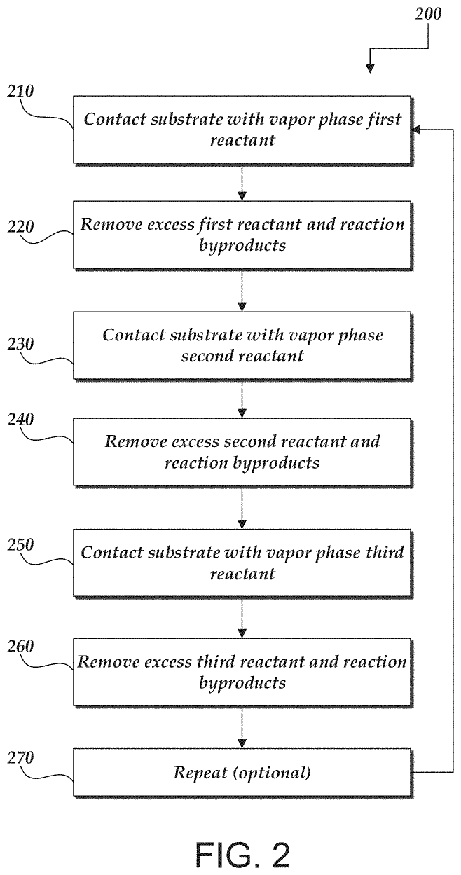

FIG. 2 is a flow-chart illustrating a deposition process 200 for depositing a thin film comprising tungsten according to some embodiments. Referring to FIG. 2, the thin film comprising tungsten is deposited on a substrate in a reaction space by a deposition process 200. The depositing process 200 comprises at least one deposition cycle comprising contacting the surface of the substrate with a first reactant comprising a tungsten precursor at block 210, removing excess tungsten precursor and reaction byproducts, if any, from the surface at block 220, contacting the surface of the substrate with a vapor phase second reactant at block 230, removing any excess second reactant and reaction byproducts, if any, from the surface of the substrate at block 240, contacting the surface of the substrate with a vapor phase third reactant at block 250, and removing any excess third reactant and reaction byproducts, if any, from the surface of the substrate at block 260. The contacting and removing steps 210-260 can optionally be repeated at block 270 form the thin film comprising tungsten of a desired thickness. For example, W thin films can be deposited.

In some embodiments, the tungsten precursor may comprise a tungsten oxyhalide, such as WOₓCl_{y}. For example, the tungsten precursor may comprise at least one of WO₂Cl₄, or WOCl₄. In some embodiments, the tungsten precursor may consist of at least one of WO₂Cl₄, or WOCl₄.

In some embodiments, the second reactant may be a first reducing agent. In some embodiments the second reactant may comprise carbon and oxygen, such as carbon monoxide (CO). In some embodiments, the second reactant may consist of carbon and oxygen, such as carbon monoxide (CO).

In some embodiments, the third reactant may comprise a second reducing agent. In some embodiments the third reactant may comprise hydrogen, such as H₂. In some embodiments, the third reactant may consist of hydrogen, such as H₂.

In some embodiments, W films may be deposited by the process illustrated in FIG. 2. In some embodiment, the tungsten precursor comprises a tungsten oxyhalide, such as WOCl₄ or WO₂Cl₄, the second reactant comprises CO, and the third reactant comprises H₂. In some embodiment, the second reactant comprises H₂, and the third reactant comprises CO. In some embodiments the only reactants used in the deposition cycle are the first reactant, second reactant and third reactant. In some embodiments the only reactants used in the deposition cycle are the tungsten precursor, CO and H₂.

In some embodiments, W films are deposited by a deposition cycle comprising alternately and sequentially contacting a substrate with a first reactant comprising tungsten hexacarbonyl precursor, a second reactant comprising an oxidant, such as H₂O, and a third reactant comprising a reducing agent, such as CO. In some embodiments the tungsten precursor can be W(CO)₆. In some embodiments the second reactant can be H₂O. In some embodiments the third reactant can be CO. In some embodiments the only reactants used in the deposition cycle are the first reactant comprising the tungsten precursor, the second reactant comprising an oxidant and the third reactant comprising a reducing agent. In some embodiments the only reactants used in the deposition cycle are the tungsten precursor, H₂O and CO.

In some embodiments the above described cyclical deposition process 200 may be an ALD type process. In some embodiments the cyclical deposition process 200 may be an ALD process. In some embodiments the above-described cyclical process 200 may be a hybrid ALD/CVD or cyclical CVD process.

Although the illustrated deposition cycle begins with contacting the surface of the substrate with the first reactant comprising the vapor phase tungsten precursor 210, in other embodiments the deposition cycle may begin with contacting the surface of the substrate with the second reactant 230 or the third reactant 250.

In some embodiments removing the precursors or reactant and any excess reaction byproducts at blocks 220, 240, 260 may comprise purging the reaction space or reaction chamber. Purging the reaction chamber may comprise the use of a purge gas and/or the application of a vacuum to the reaction space. Where a purge gas is used, the purge gas may flow continuously or may be flowed through the reaction space only after the flow of a reactant gas has been stopped and before the next reactant gas begins flowing through the reaction space. It is also possible to continuously flow a purge or non-reactive gas through the reaction chamber so as to utilize the non-reactive gas as a carrier gas for the various reactive species. Thus, in some embodiments, a gas, such as nitrogen, continuously flows through the reaction space while the tungsten precursor and reactant are pulsed as necessary into the reaction chamber. Because the carrier gas is continuously flowing, removing excess reactant or reaction by-products is achieved by merely stopping the flow of reactant gas into the reaction space.

In some embodiments removing the precursors or reactant and any excess reaction byproducts at blocks 220, 240, 260 may comprise moving the substrate from a first reaction chamber to a second, different reaction chamber. In some embodiments removing the precursors or reactant and any excess reaction byproducts at blocks 220, 240, 260 may comprise moving the substrate from a first reaction chamber to a second, different reaction chamber under a vacuum.

In some embodiments the deposited thin film comprising tungsten may be subjected to a treatment process after deposition. In some embodiments this treatment process may, for example, enhance the conductivity or continuity of the deposited thin film comprising tungsten. In some embodiments a treatment process may comprise, for example an anneal process.

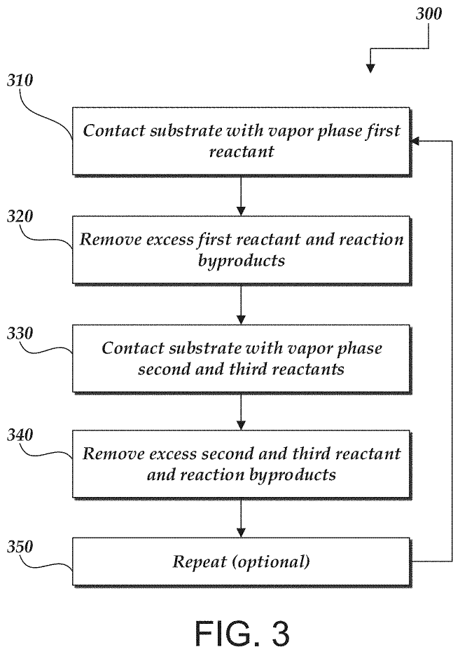

FIG. 3 is a flow-chart illustrating a deposition process 300 for depositing a thin film comprising tungsten according to some embodiments. The deposition process 300 is similar to the deposition process 200 except that the second reactant and the third reactant may be contacted with the substrate at the same time, such as by being flowed together into the reaction space. The deposition process 300 comprises at least one deposition cycle comprising contacting the surface of the substrate with a first reactant comprising a vapor phase tungsten precursor at block 310, removing any excess tungsten precursor and reaction byproducts, if any, from the surface at block 320, simultaneously contacting the surface of the substrate with a vapor phase second reactant and a vapor phase third reactant at block 330, and removing excess second and third reactants and reaction byproducts, if any, from the surface of the substrate at block 340. The deposition cycle comprising the contacting and removing steps 310-340 can be repeated at block 350 to form the thin film comprising tungsten of a desired thickness. For example, W thin films can be deposited.

As indicated in FIG. 3, in some embodiments the tungsten precursor may comprise a tungsten oxyhalide, such as WOₓCl_{y}. However, other tungsten precursors may be used. For example, the tungsten precursor may comprise at least one of WO₂Cl₄, or WOCl₄. In some embodiments, the precursors may consist of at least one of WO₂Cl₄, or WOCl₄.

In some embodiments, the second reactant may comprise a reducing agent. In some embodiments the second reactant may comprise a compound comprising carbon and oxygen, such as carbon monoxide (CO). In some embodiments, the third reactant may comprise a second reducing agent. In some embodiments the third reactant comprises hydrogen, such as H₂. In some embodiments the second reactant may comprise CO and the third reactant may comprise H₂.

In some embodiments, a second reactant comprising CO and a third reactant comprising H₂ may be flowed into the reaction chamber together. In some embodiments, the precursor, and the reactants may be supplied with a carrier gas. In some embodiments, the co-flow of the second reactant and the third reactant may consist of CO, and H₂.

In some embodiments the first reactant comprising the tungsten precursor can be a tungsten hexcarbonyl (W(CO)₆). In some embodiments, W films are deposited by a deposition cycle comprising contacting a substrate with a first reactant comprising a tungsten hexacarbonyl precursor, a second reactant comprising an oxidant, such as H₂O, and a third reactant comprising a reducing agent, such as CO.

In some embodiments as illustrated in FIG. 3, the second reactant and the third reactant may be flowed into the reaction chamber together. For example, H₂O and CO may be pulsed into the reaction chamber together to contact the substrate and react with adsorbed tungsten species. In some embodiments, the precursor and the reactants may be supplied with the aid of a carrier gas.

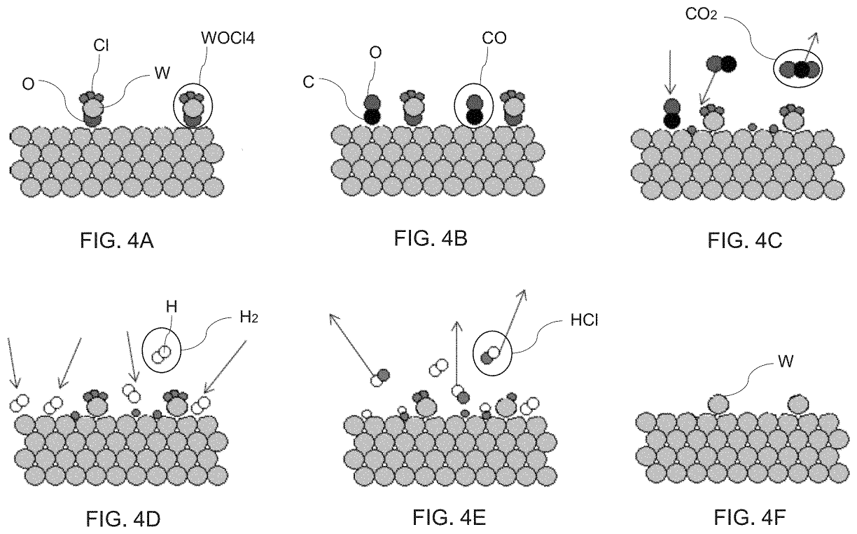

FIGS. 4A-4F are diagrams illustrating each step of deposition process for depositing a metallic film comprising tungsten by an ALD deposition cycle according to certain embodiments. A purging step may be performed between each of the contacting steps. In the illustrated embodiment, WOCl₄ is used as the tungsten precursor, the second reactant is CO, and the third reactant is H₂. However, other tungsten precursors and reactants may be used as discussed herein.

Referring to FIG. 4A, a precursor comprising tungsten, e.g., WOCl₄, is contacted with a surface of a substrate on which a tungsten-containing film is to be deposited. Species of the tungsten precursor adsorb on the substrate surface. Referring to FIGS. 4B-4C, a second reactant, e.g., CO, is contacted with the surface to which the precursor species are adsorbed. The CO reacts with the adsorbed species to remove oxygen. CO₂ is formed from the reaction between the CO and the adsorbed precursor species. The CO₂ can be removed from the reaction space, for example by purging.

When the oxygen is removed, WCl₄ remains and some Cl is adsorbed to the surface. Referring to FIG. 4D, a third reactant, e.g., H₂ is contacted with the surface and reacts with the WCl₄ to form HCl gas that can be removed from the reaction space, for example by purging.

Accordingly, tungsten remains on the substrate surface, as illustrated in FIG. 4F.

### Thin Film Characteristics

Thin films comprising tungsten deposited according to some of the embodiments described herein may be continuous thin films comprising tungsten. In some embodiments the thin films comprising tungsten deposited according to some of the embodiments described herein may be continuous at a thickness below about 100 nm, below about 60 nm, below about 50 nm, below about 40 nm, below about 30 nm, below about 25 nm, or below about 20 nm or below about 15 nm or below about 10 nm or below about 5 nm or lower. The continuity referred can be physically continuity or electrical continuity. In some embodiments, the thickness at which a film may be physically continuous may not be the same as the thickness at which a film is electrically continuous, and the thickness at which a film may be electrically continuous may not be the same as the thickness at which a film is physically continuous.

While in some embodiments a thin film comprising tungsten deposited according to some of the embodiments described herein may be continuous, in some embodiments it may be desirable to form a non-continuous thin film comprising tungsten, or a thin film comprising separate islands or nanoparticles comprising tungsten. In some embodiments the deposited thin film comprising tungsten may comprise nanoparticles comprising tungsten that are not substantially physically or electrically continuous with one another. In some embodiments the deposited thin film comprising tungsten may comprise separate nanoparticles, or separate islands, comprising tungsten.

In some embodiments a thin film comprising tungsten deposited according to some of the embodiments described herein may have a resistivity of less than about 20 μΩcm at a thickness of less than about 100 nm. In some embodiments a thin film comprising tungsten deposited according to some of the embodiments described herein may have a resistivity of less than about 20 μΩcm at a thickness of below about 60 nm, below about 50 nm, below about 40 nm, below about 30 nm, below about 25 nm, or below about 20 nm or lower. In some embodiments a thin film comprising tungsten deposited according to some of the embodiments described herein may have a resistivity of less than about 15 μΩcm at a thickness of below about 60 nm, below about 50 nm, below about 40 nm, below about 30 nm, below about 25 nm, or below about 20 nm or lower. In some embodiments a thin film comprising tungsten deposited according to some of the embodiments described herein may have a resistivity of less than about 10 μΩcm at a thickness of below about 60 nm, below about 50 nm, below about 40 nm, below about 30 nm, below about 25 nm, or below about 20 nm or lower. In some embodiments a thin film comprising tungsten deposited according to some of the embodiments described herein may have a resistivity of less than about 200 μΩcm at a thickness of below about 30 nm, below about 20 nm, below about 15 nm, below about 10 nm, below about 8 nm, or below about 5 nm or lower.

In some embodiments a thin film comprising tungsten deposited according to some of the embodiments described herein may have a resistivity of less than about 200 μΩcm, less than about 100 μΩcm, less than about 50 μΩcm, less than about 30 μΩcm, less than about 20 μΩcm, less than about 18 μΩcm, less than about 15 μΩcm, less than about 12 μΩcm, less than about 10 μΩcm, less than about 8 μΩcm, or less than about 5 μΩcm or lower at a thickness of less than about 100 nm. In some embodiments a thin film comprising tungsten deposited according to some of the embodiments described herein may have a resistivity of less than about 20 μΩcm, less than about 18 μΩcm, less than about 15 μΩcm, less than about 12 μΩcm, less than about 10 μΩcm, less than about 8 μΩcm, or less than about 5 μΩcm or lower at a thickness of less than about 50 nm.

In some embodiments a W film is deposited to a thickness of less than about 10 nm, more preferably less than about 5 nm and most preferably less than about 3 nm.

Atomic layer deposition allows for conformal deposition of tungsten-containing films. In some embodiments, the tungsten films deposited by the processes disclosed herein on a three-dimensional structure have at least 90%, 95% or higher conformality. In some embodiments the films are about 100% conformal.

In some embodiments, the tungsten film formed has step coverage of more than about 80%, more preferably more than about 90%, and most preferably more than about 95% in structures which have high aspect ratios. In some embodiments high aspect ratio structures have an aspect ratio that is more than about 3:1 when comparing the depth or height to the width of the feature. In some embodiments the structures have an aspect ratio of more than about 5:1, or even an aspect ratio of 10:1 or greater.

In some embodiments, the tungsten films deposited by processes disclosed herein are annealed after the deposition, as desired, depending on the application. In some embodiments the tungsten films are annealed in an oxygen environment. For example, the films may be annealed at an elevated temperature in water or O₂. In some embodiments an annealing step is not carried out.

In some embodiments, following deposition, a further film is deposited over the tungsten film. The additional film may be directly over and contacting the ALD-deposited tungsten film.

Although certain embodiments and examples have been discussed, it will be understood by those skilled in the art that the scope of the claims extend beyond the specifically disclosed embodiments to other alternative embodiments and/or uses and obvious modifications and equivalents thereof.

What is claimed is:

1. A process for forming a thin film comprising tungsten on a substrate in a reaction space, the process comprising a plurality of deposition cycles comprising:
contacting the substrate with a first reactant comprising a vapor phase tungsten oxyhalide;
contacting the substrate with a second reactant comprising CO; and
contacting the substrate with a third reactant comprising H₂,
wherein the deposition cycle is repeated to form the thin film comprising tungsten.

2. The process of claim 1, wherein the deposition cycle further comprises removing excess vapor phase tungsten precursor and reaction byproducts, if any, from the reaction space after contacting the substrate with the first reactant and prior to contacting the substrate with the second and the third reactants.

3. The process of claim 1, wherein the substrate is alternately and sequentially contacted with the first reactant, the second reactant and the third reactant.

4. The process of claim 1, wherein the substrate is simultaneously contacted with the second reactant and the third reactant

5. The process of claim 1, wherein the tungsten precursor comprises at least one of WO₂Cl₄, or WOCl₄.

6. The process of claim 5, wherein the thin film is a tungsten thin film.

7. The process of claim 1, further comprising:
contacting the substrate with an oxygen reactant.

8. The process of claim 7, wherein the oxygen reactant comprises at least one of H₂O, O₃, H₂O₂, N₂O, NO₂ or NO.

9. The process of claim 1, wherein the only reactants that are used in the deposition cycle are the first, second and third reactants.

10. The process of claim 1, wherein the deposition cycle comprises, in order:
contacting the substrate with the vapor phase tungsten precursor;
contacting the substrate with the second reactant comprising CO; and
contacting the substrate with the third reactant comprising H₂.

11. The process of claim 1, wherein the deposition cycle comprises, in order:
contacting the substrate with the vapor phase tungsten precursor; and
contacting the substrate simultaneously with the second reactant and the third reactant.

12. The process of claim 1, wherein the process is an atomic layer deposition process.

13. A process for forming a thin film comprising tungsten on a substrate in a reaction space, the process comprising a plurality of deposition cycles comprising:
contacting the substrate with a first reactant comprising a vapor phase tungsten precursor comprising W(CO)₆;
contacting the substrate with a second reactant comprising H₂O; and
contacting the substrate with a third reactant comprising CO,
wherein the deposition cycle is repeated to form the thin film comprising tungsten.

14. The process of claim 13, wherein the deposition cycle further comprises removing excess vapor phase tungsten precursor and reaction byproducts, if any, from the reaction space after contacting the substrate with the vapor phase tungsten precursor and prior to contacting the substrate with the second and the third reactants.

15. The process of claim 13, wherein the only reactants that are used in the deposition cycle are the first, second and third reactants.

16. The process of claim 13, wherein the deposition cycle comprises, in order:
contacting the substrate with the vapor phase tungsten precursor;
contacting the substrate with the second reactant comprising H₂O; and
contacting the substrate with the third reactant comprising CO.

17. The process of claim 13, wherein the deposition cycle comprises, in order:
contacting the substrate with the vapor phase tungsten precursor; and
contacting the substrate simultaneously with the second reactant and the third reactant.

18. The process of claim 13, wherein the process is an atomic layer deposition process.

19. The process of claim 13, wherein the deposition temperature is from about 200° C. to about 500° C.

20. The process of claim 13, wherein the thin film is an elemental tungsten film.
